(19) United States
(12) Patent Application Publication
(10) Pub. No.: US 2012/0320447 A1
(43) Pub. Date: Dec. 20, 2012

(54) SEMICONDUCTOR LASER, SURFACE EMITTING SEMICONDUCTOR LASER, SEMICONDUCTOR LASER MODULE, AND NON-LINEAR OPTICAL DEVICE

(75) Inventors: Keishi TAKAKI, Tokyo (JP); Hirotatsu ISHII, Tokyo (JP); Norihiro IWAI, Tokyo (JP); Shinya OOTOMO, Tokyo (JP)

(73) Assignee: FURUKAWA ELECTRIC CO., LTD., Tokyo (JP)

(21) Appl. No.: 13/330,857

(22) Filed: Dec. 20, 2011

Related U.S. Application Data
(63) Continuation of application No. PCT/JP2011/003431, filed on Jun. 16, 2011.

(51) Int. Cl. G02F 1/37; H01S 5/183

(52) U.S. Cl. 359/328; 372/45.01

(57) ABSTRACT

There is provided a semiconductor laser that includes a dielectric multilayer mirror (116) with a structure including high-refractive-index dielectric layers and low-refractive-index dielectric layers arranged periodically, and a cavity (110) that includes the dielectric multilayer mirror (116), on at least one facet thereof, and an active layer (105). A non-linear layer that is non-linear with respect to primary mode laser light is formed in at least one layer of either the high-refractive-index dielectric layers or the low-refractive-index dielectric layers.

### BACKGROUND

1. Technical Field

The present invention relates to a semiconductor laser, a surface emitting semiconductor laser, a semiconductor laser module, and a non-linear optical device. In particular, the present invention relates to a vertical cavity surface emitting semiconductor laser, a semiconductor laser module using this surface emitting semiconductor laser, and a non-linear optical device for generating a second harmonic. The contents of the following PCT application are incorporated herein by reference: No. PCT/JP2011/003431 filed on Jun. 16, 2011.

2. Related Art

U.S. Pat. No. 6,916,672 and U.S. Pat. No. 6,750,071 each disclose, as a conventional surface emitting semiconductor laser, a vertical cavity surface emitting semiconductor laser including a plurality of semiconductor layers, in which an active layer is contained between upper and lower multilayer reflective mirrors, which are DBR (Distributed Bragg Reflector) mirrors. Each surface emitting semiconductor laser includes a mesa post structure and a current confinement layer for increasing the current injection efficiency by confining the current path. The current confinement layer includes a current confinement portion made of Al₂O₃ and positioned on the periphery and a circular current injection portion made of AlAs and positioned in the center of the current confinement portion. The current injection portion serves as an opening for emitting laser light and as a current path when current is injected to the surface emitting semiconductor laser. A surface emitting semiconductor laser with this configuration can be expected to be used in an array-type ultra-high-speed parallel optical link for a plurality of devices, for example, and it is necessary to monitor the optical output of this link. Monitoring of the optical output of the surface emitting semiconductor laser is usually performed by extracting a portion of the primary mode oscillation wavelength component as monitor light, and a photodetector, e.g. a monitor PD (photodiode), is used for this monitoring. For example, when a CAN packaged surface emitting semiconductor laser module is used, an inclined mirror having a low-reflection film thereon is provided on the upper portion of the emitting surface of the surface emitting semiconductor laser to split and direct the monitor light to the photodetector used for monitoring.

Another technique, which is disclosed in U.S. Pat. No. 6,243,407 and Jpn. J. Appl. Phys. vol. 35 (1996), pp. 2559-2664, includes using second harmonic generation (SHG) as a means for acquiring light with a wavelength differing from the primary mode oscillation wavelength in the surface emitting semiconductor laser. In order to perform the SHG efficiently, U.S. Pat. No. 6,243,407 discloses a structure in which an SHG conversion device is housed in an external cavity and resonance is achieved between the SHG conversion device and an external mirror, and Jpn. J. Appl. Phys. vol. 35 (1996), pp. 2559-2664 discloses introducing a semiconductor super lattice layer into the cavity.

However, in a case where the surface emitting semiconductor laser is used as an optical link, for example, to form an array, when the usual output monitoring method is used for the surface emitting semiconductor laser, it is necessary to connect a monitoring photodetector in correspondence with each surface emitting laser. When such a structure is mounted in a surface emitting semiconductor laser module, a large amount of space is taken up, and this makes it difficult to conserve space in the module. Furthermore, the method for forming the second harmonic using the SHG effect in U.S. Pat. No. 6,243,407 uses an external cavity, and therefore cannot be used for high-speed modulation. Yet further, the structure disclosed in Jpn. J. Appl. Phys. vol. 35 (1996), pp. 2559-2664 has a problem that the fundamental wave is absorbed by the supper lattice layer in the waveguide, and therefore it is difficult to generate the second harmonic while maintaining basic performance such as the drive characteristics and the quantum efficiency.

The present invention has been achieved in view of the above problems, and it is an object of the present invention to provide a semiconductor laser and a surface emitting semiconductor laser that can generate a second harmonic for output monitoring, while enabling space to be conserved and avoiding degradation of basic performance such as drive characteristics and quantum efficiency, and to also provide a semiconductor laser module using the semiconductor laser or the surface emitting semiconductor laser and a non-linear optical device.

### SUMMARY

According to a first aspect related to the innovations herein, there is provided a surface emitting semiconductor laser, which includes a first reflective mirror, a second reflective mirror that faces the first reflective mirror, and a cavity that is formed between the first reflective mirror and the second reflective mirror and includes an active layer. The first reflective mirror is a dielectric multilayer mirror having a structure in which high-refractive-index dielectric layers and low-refractive-index dielectric layers are arranged periodically, and at least one of the first reflective mirror and the cavity includes a non-linear layer that is non-linear with respect to primary mode laser light.

According to a second aspect related to the innovations herein, there is provided a non-linear optical device, which includes a dielectric multilayer film with a structure including high-refractive-index dielectric layers and low-refractive-index dielectric layers arranged periodically, and a non-linear layer that is non-linear with respect to primary mode laser light propagated therethrough and is formed in at least one layer of either the high-refractive-index dielectric layers or the low-refractive-index dielectric layers.

According to a third aspect related to the innovations herein, there is provided a semiconductor laser, which includes a dielectric multilayer mirror with a structure including high-refractive-index dielectric layers and low-refractive-index dielectric layers arranged periodically, and a cavity that includes the dielectric multilayer mirror, on at least one facet thereof, and an active layer. A non-linear layer that is non-linear with respect to primary mode laser light is formed in at least one layer of either the high-refractive-index dielectric layers or the low-refractive-index dielectric layers.

### BRIEF DESCRIPTION OF THE DRAWINGS

FIG. 1 shows a schematic cross section of the surface emitting semiconductor laser according to the present embodiment;

FIG. 2 shows the waveform dependency of the refractive index of the non-linear SiₓN_{y} used as the non-linear layer of the surface emitting semiconductor laser shown in FIG. 1;

FIG. 3 is a graph of measurement results for the oscillation spectrum of the second harmonic when the high-refractive-index layer of the dielectric multilayer film of the surface emitting semiconductor laser shown in FIG. 1 is a non-linear layer; and

FIG. 4 schematically shows a surface emitting semiconductor laser module using the surface emitting semiconductor laser shown in FIG. 1.

### DESCRIPTION OF EXEMPLARY EMBODIMENTS

Exemplary embodiments of the present invention will be described in detail below with reference to accompanying drawings. However, the embodiments should not be construed to limit the invention. All the combinations of the features described in the embodiments are not necessarily essential to means provided by aspects of the invention.

An example of a surface emitting semiconductor laser according to an embodiment of the present invention is a surface emitting semiconductor laser with a laser oscillation wavelength in the 1060 nm band.

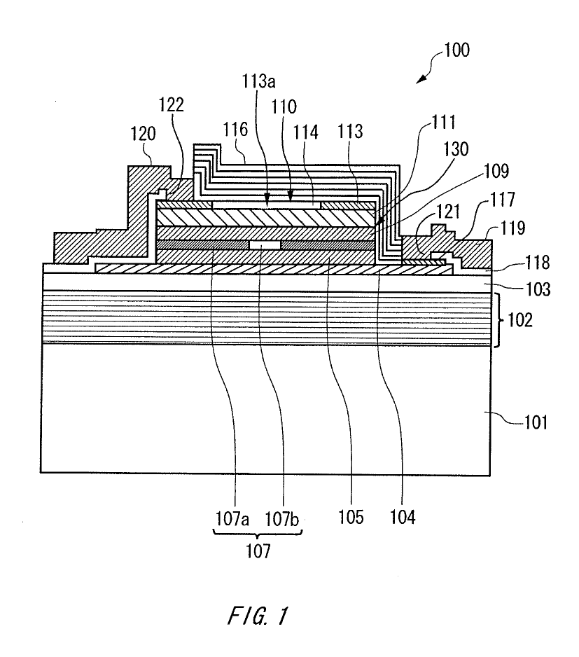

FIG. 1 shows a schematic cross section of the surface emitting semiconductor laser 100 according to the present embodiment. As shown in FIG. 1, the surface emitting semiconductor laser 100 has a structure formed by sequentially layering a substrate 101, a lower DBR mirror 102 that is a lower semiconductor multilayer reflective mirror formed on the substrate 101, a buffer layer 103, an n-type contact layer 104, an active layer 105 that has a multiple quantum well structure, a current confinement layer 107 that includes a current confinement portion 107a positioned at the periphery and a circular current injection portion 107b positioned at the center of the current confinement portion 107a, a p-type spacer layer 109, a and p⁺-type contact layer 111. A cylindrical mesa post 130 is formed from the active layer 105 to the p⁺-type contact layer 111.

When the laser oscillation wavelength is in the 1060 nm band, the substrate 101 may be made of an undoped GaAs (100) substrate. The lower DBR mirror 102 is made of 34 pairs of GaAs/Al_{0.9}Ga_{0.1}As layers. The buffer layer 103 is made of undoped GaAs. The n-type contact layer 104 is made of n-type GaAs. The active layer 105 has a structure in which three InGaAs well layers and four GaAs barrier layers are layered in an alternating manner, such that the region from the bottommost GaAs barrier layer to the buffer layer 103 functions as an n-side cladding layer. In the current confinement layer 107, the current confinement portion 107a is made of Al₂O₃ and the current injection portion 107b is made of AlAs and has a diameter from 6 μm to 15 μm. The p-type spacer layer 109 and the p⁺-type contact layer 111 are respectively p-type and p⁺-type GaAs doped with carbon. The acceptor or donor density (dopant density), in each p-type or n-type layer may be less than 2×10¹⁹ cm⁻³, e.g. 1×10¹⁸ cm⁻³, and the acceptor density (dopant density) of the p⁺-type layer may be 2×10¹⁹ cm⁻³. The refractive index of each semiconductor layer made of GaAs is approximately 3.45. A ring-shaped (annular) p-side electrode 113 is formed on the p⁺-type contact layer 111. The outer diameter of the p-side electrode 113 is 30 μm, for example, and the inner diameter of an opening portion 113a therein is from 10 μm to 20 μm, for example.

A disc-shaped dielectric layer 114 made of silicon nitride (SiₓN_{y}), for example, is formed in the opening portion 113a of the p-side electrode 113. The phase of a standing wave in a cavity is adjusted using the dielectric layer 114. In this case, the region from the topmost GaAs barrier layer to the dielectric layer 114 functions as a p-side cladding layer. The region from the top surface of the dielectric layer 114 functioning as the phase adjustment layer to the bottom surface of the buffer layer 103 forms the cavity 110.

An upper DBR mirror 116, which is an upper multilayer reflective mirror made of a dielectric is formed on the periphery of the mesa post 130 from above the p-side electrode 113 and the dielectric layer 114. The upper DBR mirror 116 is a dielectric multilayer mirror having a structure of periodic high-refractive-index dielectric layers and low-refractive-index dielectric layers, and is made of 10 to 12 pairs of SiₓN_{y}/SiO₂, for example.

The n-type contact layer 104 extends radially outward from the bottom of the mesa post 130, and a semi-annular n-side electrode 117 made of AuGeNi/Au, for example, is formed on the surface of the n-type contact layer 104. The n-side electrode 117 has an outer diameter of 80 μm and an inner diameter of 40 μm, for example. In order to protect the surface, a passivation film 118 made of a dielectric such as SiO₂ is formed over the entire surface. The SiO₂ of the passivation film 118 also functions as the SiO₂ of the bottommost layer of the upper DBR mirror 116. Accordingly, the bottommost layer of the upper DBR mirror 116 of SiₓN_{y}/SiO₂ is the SiO₂ of the passivation film 118, and the upper DBR mirror 116 of SiₓN_{y}/SiO₂ has a structure in which SiₓN_{y} and SiO₂ are formed thereon in an alternating manner, such that the topmost layer is SiₓN_{y}.

An n-side lead electrode 119 made of Au is formed in a manner to contact the n-side electrode 117 via an opening portion 121 formed in the passivation film 118. A p-side lead electrode 120 made of Au is formed in a manner to contact the p-side electrode 113 via an opening portion 122 formed in the passivation film 118. The n-side electrode 117 and the p-side electrode 113 are electrically connected to an external current supply circuit (not shown) by the n-side lead electrode 119 and the p-side lead electrode 120, respectively.

The surface emitting semiconductor laser 100 applies voltage from the current supply circuit between the n-side electrode 117 and the p-side electrode 113, via the n-side lead electrode 119 and the p-side lead electrode 120. When the current is injected, the current flows mainly through the p⁺-type contact layer 111 having low resistance and the current path is further confined in the current injection portion 107b by the current confinement layer 107, resulting in the current being supplied to the active layer 105 with a high current density. As a result, the active layer 105 is injected with carriers to emit spontaneously emitted light. Within the spontaneously emitted light, light of the wavelength X, which is the laser oscillation wavelength, forms a standing wave in the cavity 110 between the lower DBR mirror 102 and the upper DBR mirror 116, and this standing wave is amplified by the active layer 105. When the supplied current becomes greater than or equal to a threshold value, the light forming the standing wave is laser oscillated, thereby outputting laser light in the 1060 nm band from the opening portion 113a of the p-side electrode 113 in the <100> direction of the substrate 101.

In the present invention, a non-linear layer that is optically non-linear with respect to the primary mode laser light is formed on at least one of the dielectric layer 114 and the upper DBR mirror 116. For example, a SiₓN_{y} film with a refractive index of 2.36 for a wavelength of 1060 nm, which is the oscillation wavelength of the primary mode laser light, may be formed on at least one of the SiₓN_{y} film forming the dielectric layer 114 and at least one layer of the SiₓN_{y} film forming the upper DBR mirror 116. Hereinafter, this SiₓN_{y} is referred to as non-linear SiₓN_{y}.

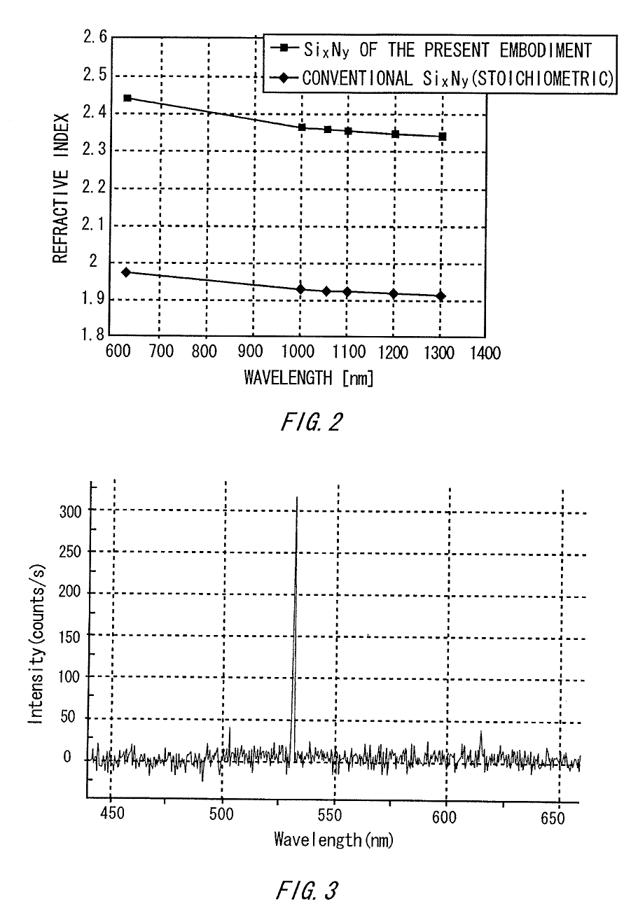

FIG. 2 shows the waveform dependency of the refractive index of the non-linear SiₓN_{y} used in the present embodiment, together with the waveform dependency of the refractive index of conventional SiₓN_{y} (stoichiometric composition of x:y 3:4, for example). The non-linear SiₓN_{y} used in the present embodiment uses nitrogen (N₂) gas and silane (SiH₄) gas as the raw material gas, and can perform deposition via plasma CVD. When depositing the non-linear SiₓN_{y}, the flow rate of the silane (SiH₄) gas relative to the nitrogen (N₂) gas is increased to be higher than when performing deposition with the conventional SiₓN_{y}. In this way, x becomes larger than y in the SiₓN_{y}, which increases the density of the SiₓN_{y}. As a result, the refractive index of the SiₓN_{y} is increased and the non-linearity of the dielectric layer 114 or the upper DBR mirror 116 is also increased, resulting in the generation of a second harmonic. The increase in the non-linearity is believed to be because the distortion in the SiₓN_{y} deposited this way is increased, thereby increasing the birefringence. The SiO₂ can be deposited using (N₂O) gas and silane (SiH₄) gas as the raw material gas, via plasma CVD. The surface emitting semiconductor laser 100 manufactured in this way simultaneously outputs, from the opening portion 113a of the p-side electrode 113, laser light in the 1060 nm band in the <100> direction of the substrate 101 and laser light in the 530 nm band, as a second harmonic, in the <100> direction of the substrate 101.

The following describes a method for manufacturing the surface emitting semiconductor laser 100.

First, epitaxial growth is used to sequentially layer, on the substrate 101, the lower DBR mirror 102, the buffer layer 103, the n-type contact layer 104, the active layer 105, an AlAs layer, the p-type spacer layer 109, and the p⁺-type contact layer 111. Furthermore, plasma CVD (Chemical Vapor Deposition) and photolithography are used to selectively form the disc-shaped dielectric layer 114 made of SiₓN_{y} on the p⁺-type contact layer 111. The optical thickness of the dielectric layer 114 is λ/4.

Next, a lift-off technique is used to form the p-side electrode 113, which is made of Pt/Ti layers, on the p⁺-type contact layer 111 at the periphery of the dielectric layer 114.

Next, a metal mask is applied to the p-side electrode 113, and an acid etching fluid, for example, is used to form the cylindrical mesa post 130 by etching the semiconductor layers to a depth reaching the n-type contact layer 104. Another mask is then formed, and the n-type contact layer 104 is etched to a depth reaching the buffer layer 103.

Next, thermal processing is performed in a water vapor atmosphere, and the Al of the AlAs layer on the active layer 105 is selectively oxidized from the periphery of the mesa post 130. At this time, a chemical reaction of 2AlAs+3H₂O→Al₂O₃+2AsH₃ occurs in the peripheral portion of the layer corresponding to the current confinement layer 107, resulting in the formation of the current confinement portion 107a. This chemical reaction progresses uniformly from the periphery of the layer corresponding to the current confinement layer 107, and therefore the current injection portion 107b of AlAs is formed in the center. Here, the thermal processing time, for example, is adjusted such that the diameter of the current injection portion 107b is from 6 μm to 15 μm. By forming the current injection portion 107b in this way, the center of the mesa post 130, the center of the current injection portion 107b, and the center of the opening portion 113a in the p-side electrode 113 can be aligned with a high degree of accuracy. As a result, the surface emitting semiconductor laser 100 can emit a multi-mode oscillated laser with good reproducibility and with a stable number of lateral modes during oscillation.

Next, the semi-annular n-side electrode 117 is formed on the surface of the n-type contact layer 104 at the periphery of the mesa post 130. Plasma CVD is then used to form the passivation film 118 of SiO₂ over the entire surface, after which the opening portions 121 and 122 are formed in the passivation film 118 above the n-side electrode 117 and the p-side electrode 113, respectively. The n-side lead electrode 119 and the p-side lead electrode 120 respectively contact the n-side electrode 117 and the p-side electrode 113 via the opening portions 121 and 122.

Next, plasma CVD is used to form the upper DBR mirror 116, after which the back surface of the substrate 101 is polished such that the substrate 101 has a thickness of 150 μm, for example. Next, dicing is performed, thereby completing the surface emitting semiconductor laser 100.

In order to manufacture a surface emitting laser with the structure shown in FIG. 1, the manufacturing method according to the embodiment of the present invention described above adopts the method of forming a non-linear layer on the upper DBR mirror 116, from among the three possible methods of forming a non-linear layer on the dielectric layer 114, forming a non-linear layer on the upper DBR mirror 116, and forming non-linear layers on both the dielectric layer 114 and the upper DBR mirror 116. In this case, the non-linear layer should be formed on at least one of the high-refractive-index dielectric layers and the low-refractive-index dielectric layers forming the upper DBR mirror 116. This non-linear layer may be formed of non-linear SiₓN_{y}, for example. In the present embodiment, in order to increase the non-linearity and improve the generation efficiency of the second harmonic, the non-linear SiₓN_{y} is formed over the entire SiₓN_{y} film, which is a high-refractive-index dielectric layer.

The non-linear SiₓN_{y} of the present embodiment is manufactured using plasma CVD, with nitrogen (N₂) gas and silane (SiH₄) gas as the raw material gas. When manufacturing the non-linear SiₓN_{y}, the flow rate of the silane (SiH₄) gas relative to the nitrogen (N₂) gas is increased to be higher than when performing deposition with the conventional SiₓN_{y}. As a result, the refractive index and the density of the SiₓN_{y} are increased and the non-linearity of the SiₓN_{y} film, and consequently the non-linearity of the upper DBR mirror 116 of SiₓN_{y}/SiO₂, is also increased, resulting in the generation of the second harmonic. The SiO₂ is manufactured using plasma CVD, with nitrogen (N₂O) gas and silane (SiH₄) gas as the raw material gas.

The oscillation wavelength spectrum of the surface emitting semiconductor laser 100 formed in this way was measured during conduction at a temperature of 25° C., and light emitted near 530 nm, as shown in FIG. 3, was obtained in addition to the primary mode laser light in the 1060 nm band.

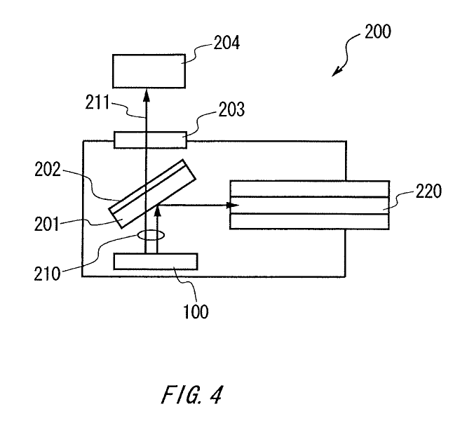

FIG. 4 shows a module 200 in which the surface emitting semiconductor laser 100 of the present embodiment is connected to an optical fiber 220.

The module 200 includes the surface emitting semiconductor laser 100, a beam splitter 201, a filter 202, and a window 203. The beam splitter 201 is made from a 45 degree half-mirror. In the present embodiment, the filter 202 absorbs light in the 1060 nm band of the primary mode from among the light directed toward the window 203, and transmits the light of the second harmonic near 530 nm.

The light 210 from the surface emitting semiconductor laser 100 is formed by the primary mode light, which in the present embodiment is light in the 1060 nm band, and the light of the second harmonic component, which in the present embodiment is light at 530 nm. The majority of this light is reflected horizontally by the beam splitter 201, to enter the optical fiber 220 used for data linking and oriented horizontally. A portion of the light 210 from the surface emitting semiconductor laser 100 is transmitted by the beam splitter 201, and the light in the 1060 nm band of the primary mode is absorbed by the filter 202 while the light 211 of the second harmonic component is emitted through the window 203 formed in the upper portion of the module to be incident to the monitor 204 positioned thereabove.

The monitor 204 is used to detect the emitted light of the second harmonic component and output the detection results, and can therefore indirectly detect the primary mode laser light in the emitted light based on the detection results. Furthermore, the monitor 204 is used to measure the brightness of the second harmonic component and output the measurement results, and can therefore indirectly detect the output of the primary mode laser light in the emitted light based on the measurement results.

In the present embodiment, the SiₓN_{y} of the upper DBR mirror 116 is non-linear and has a high refractive index, and therefore the non-linearity of the upper DBR mirror 116 is increased and the second harmonic wave is generated. Since the upper DBR mirror 116 generates the second harmonic wave for the monitor in this way, no new structures are necessary, thereby saving space. Furthermore, since there is no need to provide an external cavity structure, the surface emitting semiconductor laser 100 can be used for high speed modulation. On the other hand, a surface emitting semiconductor laser including an external cavity cannot achieve high-speed modulation, due to reasons such as the extremely long cavity. Furthermore, there is no degradation of the basic performance of the surface emitting semiconductor laser, such as occurs when the second harmonic is generated by the super-lattice layer within the semiconductor.

In the present embodiment, the second harmonic is generated by using non-linear SiₓN_{y} with a high refractive index for the upper DBR mirror 116. When manufacturing the upper DBR mirror 116, the only difference in comparison to using conventional SiₓN_{y} (stoichiometric composition: Si₃N₄) is that the flow rate of the silane (SiH₄) gas relative to the nitrogen (N₂) gas is increased, and there is no need to use a new manufacturing apparatus or a new manufacturing process, and therefore this method does not increase the manufacturing cost.

In the present embodiment, not only the primary mode light, but also the light of the second harmonic component is used as the monitor light. Accordingly, whether the primary mode light is in the 1060 nm band (from 940 nm to 1100 nm) or in the 1300 nm band (from 1150 nm to 1300 nm), the monitor light is in the visible light region with a wavelength of approximately 530 nm or 650 nm, respectively, thereby achieving excellent visibility. Accordingly, any degradation in the output of the surface emitting semiconductor laser can be recognized, and the configuration of the output monitor can be simplified.

The surface emitting semiconductor laser of the present embodiment can also be used as a light source for visible laser light.

In the present embodiment, a dielectric multilayer mirror obtained by alternately layering 10 to 12 layers of SiₓN_{y} and SiO₂ is used as the upper DBR mirror 116, and non-linear SiₓN_{y} having a refractive index with the waveform dependency shown in FIG. 2 is used as the SiₓN_{y} forming the high-refractive-index layers of the dielectric multilayer mirror. The refractive index of the non-linear SiₓN_{y} is 2.36 for a wavelength of 1060 nm, which is the oscillation wavelength of the primary mode laser light. However, it is not necessary for all of the high-refractive-index layers of the dielectric multilayer mirror to be formed of non-linear SiₓN_{y}, and only one of the layers must be formed of the non-linear SiₓN_{y}. Furthermore, as described above, the dielectric film forming the dielectric layer 114 may be formed of non-linear SiₓN_{y}. Furthermore, both the dielectric layer forming the dielectric layer 114 and at least one layer of the dielectric film forming the upper DBR mirror 116 may be formed of non-linear SiₓN_{y}.

The non-linear SiₓN_{y} used for the dielectric film of the dielectric layer or for the high-refractive-index film of the dielectric multilayer mirror is not limited to having a refractive index of 2.36 for a wavelength of 1060 nm. The second harmonic is observed when a SiₓN_{y} film with a refractive index larger than or equal to 2.2 for a wavelength of 1060 nm is used for the dielectric layer or the dielectric multilayer mirror. Accordingly, the refractive index of the non-linear SiₓN_{y} used for the dielectric layer or the dielectric multilayer mirror may be 2.2 or larger for a wavelength of 1060 nm.

On the other hand, if SiₓN_{y} with a refractive index higher than 2.5 for a wavelength of 1060 nm is used, the absorption edge of the SiₓN_{y} is longer than the primary mode oscillation wavelength, and this results in degradation of the primary mode light output, which is not desirable.

Therefore, when considering the absorption edge of SiₓN_{y}, it is preferable that the oscillation wavelength of the primary mode laser light be longer than the wavelength of the absorption edge of the SiₓN_{y}.

The oscillation wavelength of the primary mode laser light can be changed by changing the composition, the film thickness, or the number of layers forming the lower DBR mirror 102 made of multilayer semiconductor film, the active layer 105 having the multiple quantum well structure, and the upper DBR mirror 116 made of multilayer film, for example, of the surface emitting semiconductor laser 100. When the oscillation wavelength of the primary mode laser light of the surface emitting semiconductor laser 100 is changed, the second harmonic corresponding to the oscillation wavelength of the primary mode laser light can still be generated by the upper DBR mirror 116 including layers of SiO₂ and SiₓN_{y} with a refractive index greater than or equal to 2.2 for a wavelength of 1060 nm. For example, when the oscillation wavelength of the primary mode laser light is in the 1300 nm band, the second harmonic with a wavelength of 650 nm can be generated. In order to specify the non-linear SiₓN_{y} having distortion for generating the harmonic, the refractive index for a wavelength of 1060 nm is used. If SiₓN_{y} with a refractive index of 2.2 or more for a wavelength of 1060 nm is used, there is enough distortion to generate a harmonic. Therefore, a second harmonic having a wavelength corresponding to the oscillation wavelength of the primary mode laser light can be generated for a surface emitting semiconductor laser 100 whose oscillation wavelength for the primary mode laser light is in a range from 720 nm to 1660 nm.

The upper DBR mirror 116 of the present embodiment can be used in a surface emitting semiconductor laser with a different structure than the surface emitting semiconductor laser 100 of the present embodiment. In this case as well, a second harmonic having a wavelength corresponding to the oscillation wavelength of the primary mode laser light can be generated by the upper DBR mirror 116.

The dielectric multilayer mirror that can generate the second harmonic, which is obtained by alternately layering high-refractive-index layers and low-refractive-index layers, can be applied to a facet emitting semiconductor laser in addition to a surface emitting semiconductor laser. In the case of a facet emitting semiconductor laser, the second harmonic of the oscillation wavelength of the primary mode laser light can be generated by providing the dielectric multilayer mirror to one of the laser facets, or by controlling the reflectivity as needed and proving the dielectric multilayer mirror to both facets.

In the present embodiment, the dielectric multilayer mirror obtained by alternately layering non-linear SiₓN_{y} and SiO₂ is used as the component for generating the second harmonic. However, the second harmonic can be generated using a material other than SiO₂ in combination with the non-linear SiₓN_{y}. For example, favorable results can be achieved using a dielectric multilayer mirror obtained by alternately layering non-linear SiₓN_{y} and MgF, CaF₂, MgO, or Al₂O₃.

In the present embodiment, the non-linear SiₓN_{y} with a refractive index of 2.2 or more for a wavelength of 1060 nm is used as a high-refractive-index dielectric layer, but instead, a non-linear SiₓN_{y} film with a refractive index of 2.2 or more for a wavelength of 1060 nm can be used as a low-refractive-index dielectric layer while a suitable dielectric with a higher refractive index than SiₓN_{y}, such as TiO₂, is used as the high-refractive-index dielectric layer.

In the present embodiment, it is not necessary to use SiₓN_{y} for the dielectric layers forming the dielectric multilayer DBR mirror that generates the second harmonic, and TiO₂ can be used instead to form the high-refractive-index layers, with favorable results. Furthermore, materials other than SiO₂ can be used to form the low-refractive-index layers, and MgF, CaF₂, MgO, or Al₂O₃ can be used with favorable results. In this case, the second harmonic can be generated by introducing, into at least one of the high-refractive-index layers and the low-refractive-index layers, distortion that causes non-linearity sufficient for making the generated harmonic visible.

If the dielectric layer 114, which is a phase adjustment layer made of non-linear SiₓN_{y} with a refractive index of 2.2 or more for a wavelength of 1060 nm, is used, the second harmonic can be generated even when non-linear SiₓN_{y} with a refractive index of 2.2 or more for a wavelength of 1060 nm is not used for the dielectric multilayer DBR mirror.

Furthermore, the non-linear SiₓN_{y} with a refractive index of 2.2 or more for a wavelength of 1060 nm can be used for both the dielectric layer 114, which is the phase adjustment layer, and the upper DBR mirror 116 formed by the dielectric multilayer film. In this case, non-linear SiₓN_{y} with a refractive index of 2.2 or more for a wavelength of 1060 nm should be used as at least one layer among the high-refractive-index layers and the low-refractive-index layers forming the upper DBR mirror 116.

If the oscillation wavelength of the primary mode laser light is no less than 720 nm and no larger than 1660 nm, the second harmonic can be generated in the visible light region by using non-linear SiₓN_{y} with a refractive index of 2.2 or more for a wavelength of 1060 nm. This is because the non-linear SiₓN_{y} with a refractive index of 2.2 or more for a wavelength of 1060 nm has a large amount of distortion and a birefringence. In this case, a wavelength selective filter that passes light whose wavelength is no less than 360 nm and no larger than 830 nm is preferably used as the filter 202 of the module 200 described in relation to FIG. 4.

If the oscillation wavelength of the primary mode laser light is no less than 1000 nm and no larger than 1300 nm, the second harmonic can be generated to be green. In this case, a wavelength selective filter that passes light whose wavelength is no less than 500 nm and no larger than 650 nm is preferably used as the filter 202 of the module 200 described in relation to FIG. 4.

In the embodiments described above, a non-linear SiₓN_{y} film with density higher than the stoichiometric composition is used as the non-linear layer, but the non-linear layer of the present invention is not limited to a non-linear SiₓN_{y} film. Any material can be used that can form a film having optical non-linearity with respect to the primary mode laser light by setting the density to be higher than the stoichiometric composition.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention. The scope of the present invention is limited only by the following claims.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A surface emitting semiconductor laser comprising:
a first reflective mirror;
a second reflective mirror that faces the first reflective mirror; and
a cavity that is formed between the first reflective mirror and the second reflective mirror and includes an active layer, wherein
the first reflective mirror is a dielectric multilayer mirror having a structure in which high-refractive-index dielectric layers and low-refractive-index dielectric layers are arranged periodically, and
at least one of the first reflective mirror and the cavity includes a non-linear layer that is non-linear with respect to primary mode laser light.

2. The surface emitting semiconductor laser according to claim 1, wherein
the non-linear layer emits light of a second harmonic of the primary mode laser light.

3. The surface emitting semiconductor laser according to claim 2, wherein
at least one layer of either the high-refractive-index dielectric layers or the low-refractive-index dielectric layers is the non-linear layer.

4. The surface emitting semiconductor laser according to claim 3, wherein
the cavity further includes a phase adjustment layer for adjusting a phase of a standing wave in the cavity, and
the non-linear layer is further provided in the phase adjustment layer.

5. The surface emitting semiconductor laser according to claim 2, wherein
the cavity further includes a phase adjustment layer for adjusting a phase of a standing wave in the cavity, and
the non-linear layer is provided on the phase adjustment layer.

6. The surface emitting semiconductor laser according to claim 2, wherein
the non-linear layer is made of non-linear SiₓN_{y} with a refractive index for a wavelength of 1060 nm that is no less than 2.2 and no larger than 2.5.

7. The surface emitting semiconductor laser according to claim 6, wherein
an absorption edge of the non-linear SiₓN_{y} is at a shorter wavelength than an oscillation wavelength of the primary mode laser light.

8. The surface emitting semiconductor laser according to claim 7, wherein the oscillation wavelength is no less than 720 nm and no larger than 1660 nm.

9. A semiconductor laser module comprising:
the surface emitting semiconductor laser according to claim 2;
a beam splitter that splits light from the surface emitting semiconductor laser; and
a filter that blocks light of the primary mode and passes light of the second harmonic, among one of the light beams resulting from the splitting by the beam splitter.

10. A non-linear optical device comprising:
a dielectric multilayer film with a structure including high-refractive-index dielectric layers and low-refractive-index dielectric layers arranged periodically; and
a non-linear layer that is non-linear with respect to primary mode laser light propagated therethrough and is formed in at least one layer of either the high-refractive-index dielectric layers or the low-refractive-index dielectric layers.

11. The non-linear optical device according to claim 10, wherein
the non-linear layer generates light of a second harmonic of the primary mode laser light.

12. The non-linear optical device according to claim 11, wherein
the non-linear layer is made of non-linear SiₓN_{y} with a refractive index for a wavelength of 1060 nm that is no less than 2.2 and no larger than 2.5.

13. The non-linear optical device according to claim 12, wherein
an absorption edge of the non-linear SiₓN_{y} is at a shorter wavelength than an oscillation wavelength of the primary mode laser light.

14. The non-linear optical device according to claim 13, wherein
the oscillation wavelength is no less than 720 nm and no larger than 1660 nm.

15. A semiconductor laser comprising:
a dielectric multilayer mirror with a structure including high-refractive-index dielectric layers and low-refractive-index dielectric layers arranged periodically; and
a cavity that includes the dielectric multilayer mirror, on at least one facet thereof, and an active layer, wherein
a non-linear layer that is non-linear with respect to primary mode laser light is formed in at least one layer of either the high-refractive-index dielectric layers or the low-refractive-index dielectric layers.

16. The semiconductor laser according to claim 15, wherein
the non-linear layer generates light of a second harmonic component of the primary mode laser light.

17. The semiconductor laser according to claim 16, wherein
the non-linear layer is made of non-linear SiₓN_{y} with a refractive index for a wavelength of 1060 nm that is no less than 2.2 and no larger than 2.5.

18. The semiconductor laser according to claim 17, wherein
an absorption edge of the non-linear SiₓN_{y} is at a shorter wavelength than an oscillation wavelength of the primary mode laser light.

19. The semiconductor laser according to claim 18, wherein
the oscillation wavelength is no less than 720 nm and no larger than 1660 nm.

20. A semiconductor laser module comprising:
the semiconductor laser according to claim 16;
a beam splitter that splits light from the semiconductor laser; and
a filter that blocks light of the primary mode and passes light of the second harmonic, among one of the light beams resulting from the splitting by the beam splitter.
